(19) United States
(12) Patent Application Publication
(10) Pub. No.: US 2008/0290924 A1
(43) Pub. Date: Nov. 27, 2008

(54) METHOD AND APPARATUS FOR PROGRAMMABLE DELAY HAVING FINE DELAY RESOLUTION

(75) Inventors: Jason Gonzalez, Solana Beach, CA (US); Harry H. Dang, San Diego, CA (US); Vannam Dang, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/116,516

(22) Filed: May 7, 2008

Related U.S. Application Data
(60) Provisional application No. 60/939,288, filed on May 21, 2007.

(51) Int. Cl. H03H 11/26

(52) U.S. Cl. 327/276

(57) ABSTRACT

An programmable delay apparatus includes a first delay stage having a delay cell which includes a passive network, where the first delay stage is capable of providing a first time delay. The apparatus further includes a second delay stage which includes a plurality of delay cells, where each delay cell is capable of providing a second time delay which is larger than the first time delay. A method for delaying an input signal includes receiving a delay select command based upon the desired time delay, establishing a circuit path which includes at least one delay element, selected from a plurality of delay cells, according to the delay select command, wherein at least one of the plurality of delay cells includes a delay element which comprises a passive network.

### PRIORITY

This application claims benefit of U.S. Provisional Application No. 60/939,288 titled “PROGRAMMABLE DELAY METHOD AND APPARATUS,” filed May 21, 2007, the entire disclosure of this application being considered part of the disclosure of this application.

### FIELD OF DISCLOSURE

The embodiments of the disclosure relate generally to time delay circuits, and more specifically, to circuits capable of providing a programmable delay within an integrated circuit (IC).

### BACKGROUND

One challenge facing modern devices utilizing high-speed synchronous communications is properly aligning clock signals and data signals. Misalignments between such signals may reduce communication speeds and/or possibly result in data corruption. As the commercial and technical demands for faster communications increase, the tolerance for misalignment becomes more stringent, thus challenging designers to improve the delay resolution of conventional techniques for maintaining fine alignments between clock and data signals.

One approach for aligning clock and data signals is to provide a programmable delay line to delay either the clock and/or data signal. The amount of delay may be determined by calibration algorithms for obtaining the optimum delay to accomplish alignment. Conventional programmable delay lines may cover the 2.4 nano-second (ns) range and have 100 pico-second (ps) of delay resolution. Such devices may be limited to only using active components such as NAND logic circuits, multiplexers, and/or inverters for their delay cells, and their delay resolution may limited by the delay of 2 inverters or more, which may be 50 ps×2=100 ps in 65 nm or 45 nm CMOS fabrication technologies. In order to properly deskew high speed data and clock signals, 100 ps resolution may not be adequate.

Conventional architectures have been proposed which improve the resolution using differential circuits; however, such implementations may require too much power and thus may be unsuitable for use in battery-operated mobile devices such as, for example, mobile terminals.

Accordingly, there is a need for programmable delay devices having resolutions fine enough for aligning signals associated with high speed communications, while having reduced power consumption requirements suitable for implementation in mobile devices.

### SUMMARY

Exemplary embodiments of the invention are directed to apparatuses and methods programmable time delays.

In one embodiment, an apparatus for providing a programmable time delay is presented. The apparatus may comprise a first delay stage having a delay cell which includes a passive network, wherein the first delay stage is capable of providing a first time delay. The apparatus may further comprise a second delay stage which includes a plurality of delay cells, wherein each delay cell is capable of providing a second time delay which is larger than the first time delay, and wherein the first delay stage and the second delay stage are configured to delay an input signal by an aggregate time delay based upon a delay select command.

In another embodiment, a method delaying an input signal by a desired time delay is presented. The method may comprise receiving a delay select command based upon the desired time delay, establishing a circuit path which includes at least one delay element, selected from a plurality of delay cells, according to the delay select command, wherein at least one of the plurality of delay cells includes a delay element which comprises a passive network. The method may further comprise passing an input signal through the established circuit path to achieve a desired time delay of the input signal.

Another embodiment can include a device for providing a programmable time delay, comprising: means for receiving a delay select command based upon the desired time delay; means for establishing a circuit path which includes at least one delay element, selected from a plurality of delay cells, according to the delay select command, wherein at least one of the plurality of delay cells includes a delay element which comprises a passive network; and means for passing an input signal through the established circuit path to achieve a desired time delay of the input signal.

### BRIEF DESCRIPTION OF THE DRAWINGS

The accompanying drawings are presented to aid in the description of embodiments of the invention and are provided solely for illustration of the embodiments and not limitation thereof.

FIG. 1 is a block diagram of an exemplary programmable delay device.

FIG. 2 is a detailed block diagram of another exemplary programmable delay device.

FIGS. 3A, 3B are diagrams illustrating the operation of the exemplary programmable delay device shown in FIG. 2.

FIG. 4 is a diagram of an exemplary mobile device which may utilize a programmable delay device.

FIG. 5 is a flowchart depicting an exemplary process associated with a programmable delay device.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation. The term “delay elements” are used herein to designate electrical/electronic components which may be used in circuits to introduce a time delay to a signal when the signal is passed through them. Delay elements could be one or more passive components, such as resistors, capacitors, and/or inductors which may be arranged in any circuit configuration designed to provide a signal delay. Delay elements could also be one or more active components, such as buffers and/or inverters, configured to provide a signal delay. As used herein, an active component utilizes an external source of energy, in addition to the input signal, in order perform its function. For example, one or more transistors, which may be used to realize an inverter, may require biasing voltages supplied by separate current and/or voltage sources.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

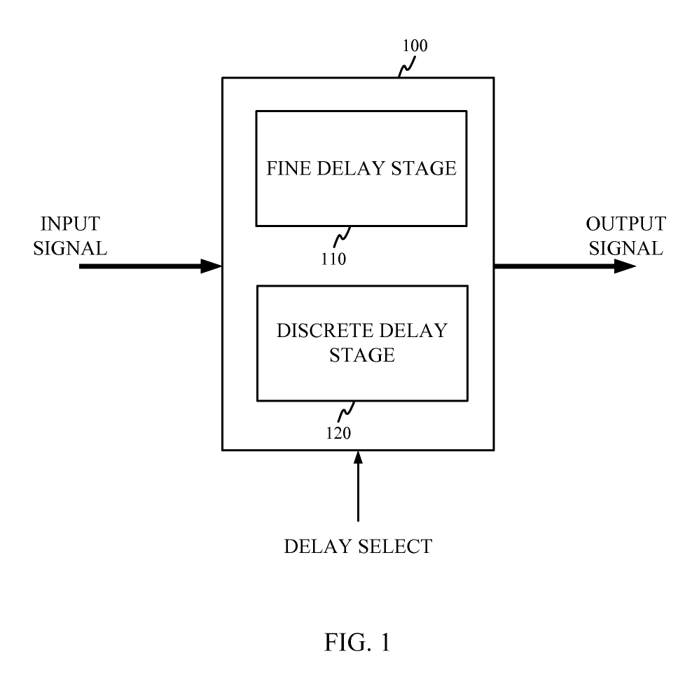

FIG. 1 is a block diagram of an exemplary programmable delay device (PDD) 100 which includes a fine delay stage 110 and a discrete delay stage 120. In various embodiments, the fine delay stage 110 may be serially coupled to the discrete delay stage 120. However, other embodiments may connect the fine and discrete delay stages in other ways which are not limited to serial connections.

The fine delay stage 100 may utilize delay elements that include one or more passive elements, such as resistors, capacitors, and/or inductors, which may be configured in any circuit that may be used to introduce a delay to a passing signal. The amount of delay introduced by the fine delay stage 100 may be determined by the type of passive components used, the value of each passive component, and/or the configuration of the circuit connecting the passive elements. Given the nature of the passive components used as delay elements, the amount of delay introduced by the fine delay stage 110 can be precisely tuned to be a small time value, thus providing for small delay resolutions. The delay provided by the fine delay stage 100 may be smaller than the delays provided in the discrete delay stage, as will be discussed below. For example, various embodiments may have a fine delay which is approximately half the delay time associated with the smallest delay provided by the discrete delay stage 120. Having such a fine delay resolution can help to mitigate quantization error.

The discrete delay stage 200 may include active components as delay elements. Such active components may include inverters, buffers, starved current inverters/buffers, multiplexors, etc. An active component used as a delay element may be designed to provide a discrete, fixed amount of time delay. Therefore, in order to increase the amount of delay, more discrete active components are added to increase the number of delay elements. Because of their nature, a single active component may provide a greater time delay than the passive components used as delay elements in the fine delay stage 100.

An input signal may be provided at the input terminal(s) of the PDD 100 so that the PPD 100 may delay the input signal by a predetermined amount of time delay. The predetermined time delay may be specified by the delay select command. The input signal may pass through the fine delay stage 110 and/or the discrete delay stage 120, and the resulting output may be the input signal delayed by an aggregate time delay determined by both delay stages 110 and 120. The aggregate delay may be the predetermined amount of time specified by the delay select command, which may be a binary word encoded with the desired amount of delay.

The input signal may be a voltage signal modulated and/or encoded by digital data. The output signal ideally is a delayed version of the input signal, but may also have a certain amount of noise introduced by the PDD 100. However, this noise should be controlled so that any signal degradation will not adversely affect the operation of the system employing the PDD 100.

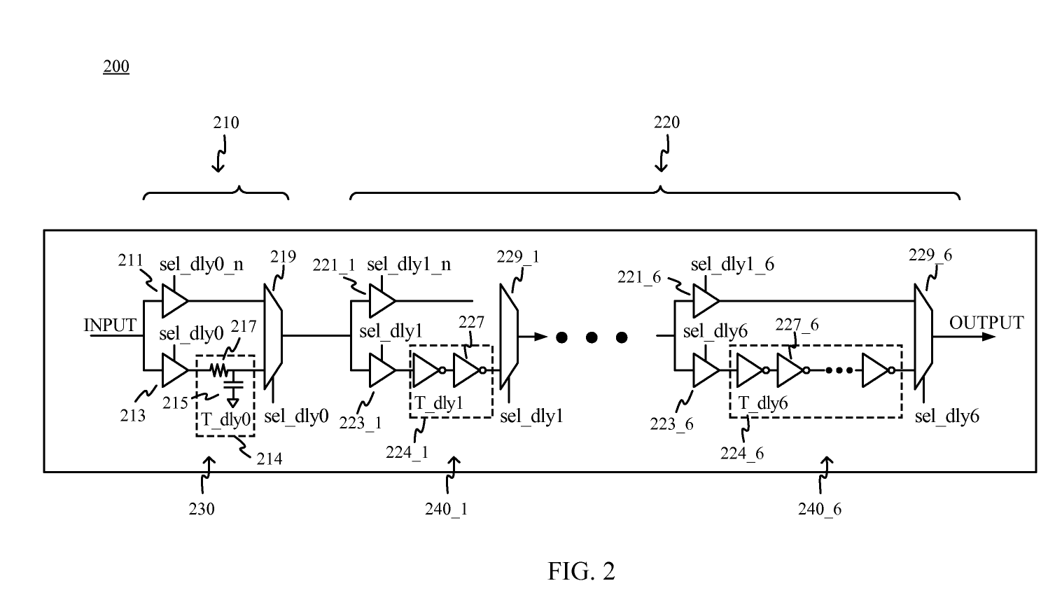

FIG. 2 is a detailed block diagram of another exemplary programmable delay device (PDD) 200 which includes a fine delay stage 210 and a discrete delay stage 220. In this embodiment, the fine delay stage 210 may only include one delay cell 230. The discrete delay stage 220 may include six delay cells 240_1 through 240_6. Each of the delay cells 230, 240_1, . . . , 240_6 may be configured in a serial manner, with the input signal entering through the fine delay stage 210, and the output signal provided by delay cell 240_6. Each delay cell 230, 240_1, . . . , 240_6 may delay the input signal by a different amount, and the effects of the delay cells may add together to produce an aggregate delay of the input signal. The delay select command may be an 8-bit word, wherein only 7 bits may be used. The individual bits of the delay select command word may represent separate signals, sel_dly0 through sel_dly6, wherein one of each signal is provided to a corresponding delay cell 230, 240_1, . . . , 240_6, respectively. These signals may “activate” or “deactivate” the circuitry responsible for creating a time delay which is unique to each delay cell 230, 240_1, . . . , 240_6.

Delay cell 230 may further include two tri-state buffers 211, 213, a multiplexer 219, and delay circuit 214. The tri-state buffer 211 may connected to one input of the multiplexer 219, the other tri-state buffer 213 may be connected to the delay circuit 214, and the delay circuit is connected to the other input of the multiplexer 219.

The delay circuit 214 may include passive components for causing a fine delay. In this embodiment, delay circuit 214 may include a resistor 217 and a capacitor 215 configured as a low pass filter. In various embodiments, the value of the capacitor may be approximately 10 femto-Farads (fF), and the value of the resistor may be approximately 166 Ohms. When combined with parasitic impedances from typical gate sizes, these values may produce a delay of approximately 25 psec, which is smaller than any of the other delay cells 240_1, . . . 240_6. Other resistor and capacitor values may be selected to alter this time delay. Moreover, other network configurations may be chosen to alter the fine time delay. In other embodiments, other circuits may be used to realize a fine time delay. For example, a fast ring oscillator could be used to generate very fine delays (for example, in 5 psec steps). Another embodiment may utilize a digital phase interpolator that could create many fine delays or phases from a reference clock. Both of these approaches could incorporate calibration methods to tune out manufacturing process skew, and produce finer delay steps. Moreover, these methods may also be easier to control and maintain monotonic delay steps, and thus simplify the timing calibration algorithms.

The operation of delay cell 230 may be described as follows. An input signal may be presented at the inputs of tri-state buffers 211, 213. Each of the tri-state buffers may be controlled by a delay select control signal sel_dly0 (the signal sel_dly0_n is the inverse of sel_dly0). Moreover, sel_dly0 is a binary signal which may correspond to the least significant bit of the delay select command word. When sel_dly0 is high (e.g., binary value “1”), tri-state buffer 213 is placed in a low impedance state, and tri-state buffer 211 is placed in a high impedance state. The multiplexer 219 selects the input which is connected to the delay circuit 230. The input signal may then flow through tri-state buffer 213 and then the delay circuit 214. After passing through the delay circuit 214, the input signal may be delayed by the minimum (e.g., 25 psec) amount, and then passed through multiplexer 219 onto the next delay cell 240_1 in discrete delay stage 220.

When sel_dly0 is set low (e.g., binary value “0”), tri-state buffer 211 is placed in a conductive state and the input connected to tri-state buffer 211 is selected on the multiplexer 219. This allows the input signal to pass through delay cell 230 with essentially no time delay (other than the propagation delay through the circuit, which may be ignored as this intrinsic delay is present for both data and clock paths. Also, tri-state buffer 213 may be placed in a high impedance state, thus preventing any parasitic current flow through the delay circuit 214. This allows the delay cell 230 to save power when it is not being used to delay the input signal.

The discrete delay stage 220, which may be coupled in series to the fine delay stage 210, may include six delay cells 240_1, . . . , 240_6. Each delay cell 240_1:6 may further include two tri-state buffers 221_1:6, 223_1:6, a multiplexer 229_1:6, and a delay circuit 224_1:6. The tri-state buffer 221_1:6 may be directly connected to one input of the multiplexer 229_1:6. The other tri-state buffer 223_1:6 may be connected to the delay circuit 224_1:6, and the delay circuit 224_1:6 may then be connected to the other input of the multiplexer 229_1:6.

Each delay cell 240_1:6 further include a delay circuit 224_1:6 which may include a plurality of active components for delay elements. In this embodiment, the each delay element may be an inverter 227, however, as mentioned above, other active components may be used. Each inverter 227 may delay a signal for a fixed, discrete amount of time (e.g., 50 ps) which is greater than the time delay provided by the fine delay cell 230. The inverters 227 may be grouped in pairs, to prevent inverting the signal at the output, with the minimum number of inverters being two for the delay circuit 224_1. The number of inverters 227 in the delay circuit for each successive delay cell 240_2, . . . , 240_6 may increase by a power of two. Accordingly, the delay cell 240_1 will impart a delay of 100 ps. Each successive time delay associated with each individual delay cell 240_2, . . . , 240_6 will be 50 ps*2ⁿ, where n takes on the integers 2, . . . , 6. In other embodiments, the number of inverters may increase linearly, logarithmically, or change in any other manner for each successive delay cell 240_1, . . . , 240_6. Moreover, in various embodiments, the number inverters may be equal for at least two of the delay cells.

The operation of each delay cell 240_1:6 may be described as follows. The signal coming from the output of delay cell 230 may be presented at the inputs of tri-state buffers 221_1:6, 223_1:6. The tri-state buffers may be controlled by a delay select control signal sel_dly1:6 (the signal sel_dly1:6_n is the inverse of sel_dly1:6). Moreover, each signal sel_dly1, . . . , sel_dly6 is a binary signal which corresponds to a respective bit in a delay select command word. The location of each bit in the select command word (that is, the “power of two” associated with each bit) corresponds to the number of each signal. For example, sel_dly1 corresponds to the second bit in command word (i.e, the 2¹'s place), sel_dly2 corresponds to the third bit in the command word, (i.e., the 2²'s place), etc.

Further referring to the operation of each delay cell 240_1:6, when sel_dly1:6 is high (e.g., binary value “1”), tri-state buffer 223_1:6 is placed in a low impedance state, and tri-state buffer 221_1:6 is placed in a high impedance state. The multiplexer 229_1:6 selects the input which is connected to the delay circuit 240_1:6. The input signal may then flow through tri-state buffer 223_1:6, and then through the delay circuit 224_1:6. After passing through the delay circuit 224_1:6, the input signal is delayed by an amount corresponding to the number of inverters 227 in the respective delay circuit 224_1:6. The signal is then passed onto the subsequent delay cell. If the delay cell in question is 240_6, the input signal has undergone all the delays in accordance with the delay select command word, and is passed along as the output signal of the PDD 200.

When sel_dly1:6 is set low (e.g., binary value “0”), tri-state buffer 221_1:6 is placed in a conductive state and the input connected to tri-state buffer 221_1:6 is selected on the multiplexer 229_1:6. This allows the input signal to pass through delay cell 240_1:6 with essentially no time delay. Also, tri-state buffer 223_1:6 may be placed in a high impedance state, thus preventing any signal current from flowing through the delay circuit 224_1:6. This allows the delay cell 240_1:6 to save power when it is not being used to delay the input signal. The power savings may come about because AC signal power is not dissipated during this state. Additional power savings may be realized by turning off the static DC (biasing) currents to the inverters by utilizing a “foot switch” to each delay buffer. The foot switch may turn off the inverters in each delay cell when they are not being used.

The PDD 200 may be realized using CMOS integrated circuit fabrication technology, and may have the advantage of using only half the layout area of conventional delay architecture. Moreover, PDD 200 may further reduce complexity because no decoding logic is required. The PDD 200 may cover the same range of time delays as a conventional delay line, but have better delay resolution (e.g., ⅙ the resolution—approximately 25 ps), and utilize only 25% more power.

Accordingly, an embodiment of the disclosure may be directed to an apparatus 200 for providing a programmable time delay, which may include a first delay stage 210 having a delay cell 230 which includes a passive network 217, wherein the first delay stage 220 is capable of providing a first time delay. The embodiment may further include a second delay stage 220 which includes a plurality of delay cells 240_1, 240_6, wherein each delay cell 240_1:6 may be capable of providing a second time delay which is larger than the first time delay, and wherein the first delay stage 210 and the second delay stage 220 are configured to delay an input signal by an aggregate time delay based upon a delay select command.

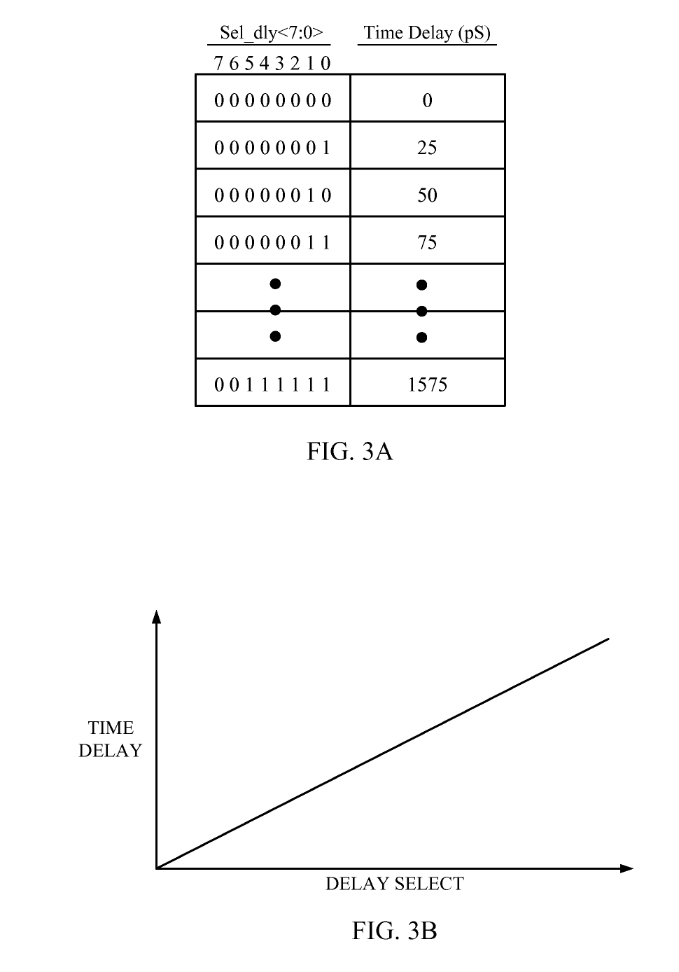

FIGS. 3A and 3B are diagrams illustrating the operation of the exemplary programmable delay device (PDD) 200. FIG. 3A depicts a table having a first column corresponding to the values which may be taken on by the delay select command word. The second column corresponds to the aggregate amount of time delay associated with the value of the delay select command word. As explained above, the bits in the delay select command word correspond to the delay select signals used to activate/deactivate the delay cells 230, 240_1, . . . , 240_6. The number corresponding to the delay select signal (sel_dly<6:0>) corresponds to the location of the corresponding bit in the delay select command word. As each successive bit is turned on, the delay associated with that bit is added to the previous delay, thus creating a cumulative or aggregate time delay. Because the number of inverters may increases in each successive delay cell 240_1, . . . , 240_6, the time delay may also increases in an associated fashion as the delay select command word increase in value, as shown in FIG. 3B.

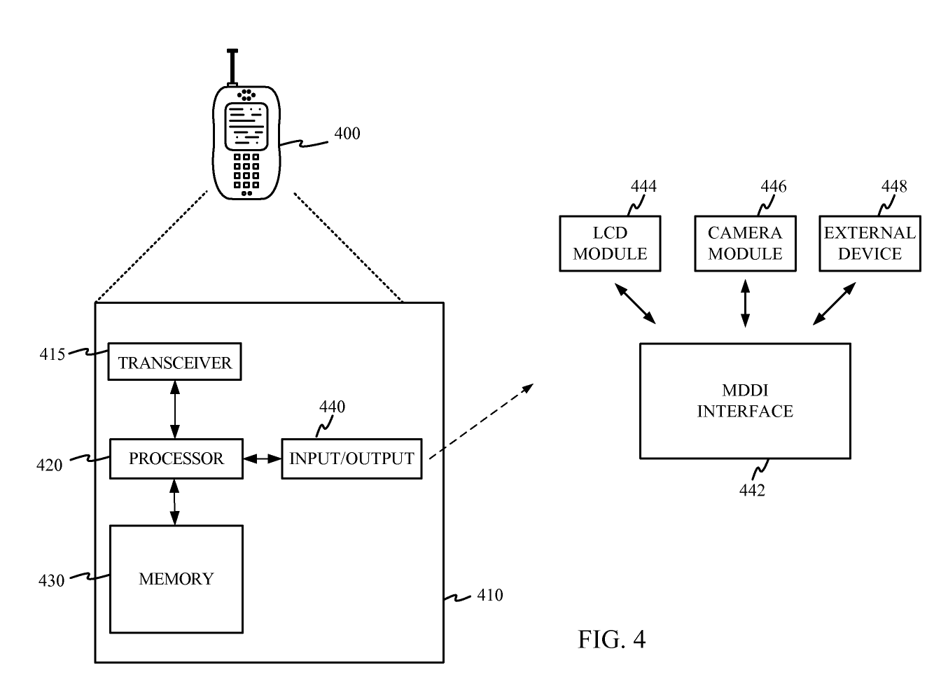

FIG. 4 is a diagram of an exemplary mobile terminal which may utilize a programmable delay device. The mobile device 400 may have a platform 410 that can exchange data and/or commands over a network. The platform 410 can include a transceiver 415, which may further include a transmitter and receiver. The transceiver may be operably coupled to a processor 420, or other controller, microprocessor, ASIC, logic circuit, or any other type of data processing device. The processor 420 may execute logic that can be stored in the memory 430 of the UE 400. The memory 430 can be comprised of read-only and/or random-access memory (RAM and ROM), EEPROM, flash cards, or any memory common to such platforms. The processor 420 may further exchange data with input/output devices 440.

The various logic elements for providing commands can be embodied in discrete elements, software modules executed on a processor or any combination of software and hardware to achieve the functionality disclosed herein. For example, the processor 420 and the memory 430 may all be used cooperatively to load, store and execute the various functions disclosed herein, and thus the logic to perform these functions may be distributed over various elements. Alternatively, the functionality could be incorporated into one discrete component (e.g., in embedded memory in the processor 420). Therefore, the features of the mobile terminal 400 in FIG. 4 are to be considered merely illustrative and the invention is not limited to the illustrated features or arrangement.

Further referring to FIG. 4, the input/output devices may be further expanded upon to include a Mobile Display Digital Interface (MDDI) interface 442, LCD module 444, a camera module 446, and an (optional) external device 448. The MDDI 440 is a high speed serial differential interface designed to connect the processor 420 to the LCD module 444 and the camera module 446 of the mobile terminal 400. The MDDI 440 may also be connected to other external devices 448, such as external display. The MDDI interface 442 may, for example, reduce the number of wires in the hinge of a flip phone, improve immunity to noise, and reduce electromagnetic interference due to its differential signaling. Within the MDDI 442, at least one PPD 100 may be used to align the clock and data signals which are transferred over the serial interfaces connecting the MDDI 442 and the other modules/devices.

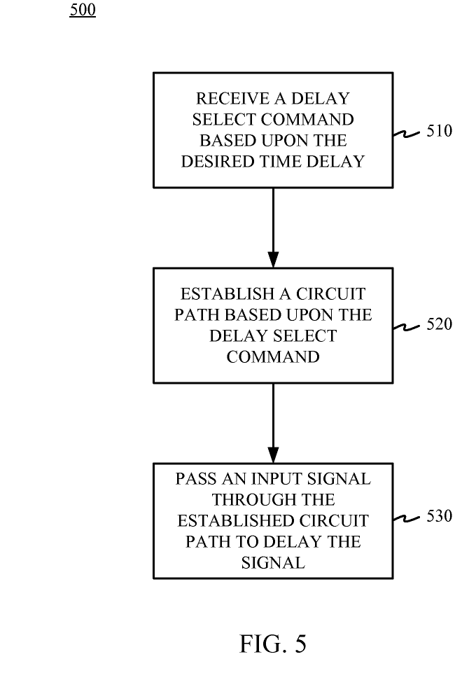

FIG. 5 is a flowchart depicting an exemplary process associated with a programmable delay device (PDD) 200. Initially, the PDD 200 may receive a delay select command based upon the desired time delay (Block 510). A circuit path may then be established by the delay cells 230 and 240_1, . . . , 240_6, based upon the value of the received delay select command (B520). Once the circuit path is established, an input signal may be passed through the established circuit path of the PDD 200 to delay the signal (B530).

Embodiments of the invention may be used in conjunction with any portable device and are not limited to the illustrated embodiments. For example, mobile terminals can include cellular telephones, access terminals, music players, radios, GPS receivers, laptop computers, personal digital assistants, and the like.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. An apparatus for providing a programmable time delay, comprising:
a first delay stage having a delay cell which includes a passive network, wherein the first delay stage is capable of providing a first time delay; and
a second delay stage which includes a plurality of delay cells, wherein each delay cell is capable of providing a second time delay which is larger than the first time delay, and
wherein the first delay stage and the second delay stage are configured to delay an input signal by an aggregate time delay based upon a delay select command.

2. The apparatus according to claim 1, wherein the first delay cell further comprises:
a first tri-state buffer coupled to the passive network;
a second tri-state buffer; and
a multiplexer coupled to the passive network and the second tri-state buffer, wherein the delay select command includes a designated bit which controls the first tri-state buffer, the second tri-state buffer, and the multiplexer.

3. The apparatus according to claim 2, wherein if the designated bit is in a high state, the multiplexer switches the passive network into a circuit path to delay the input signal by the first delay.

4. The apparatus according to claim 2, wherein if the designated bit is in a low state, the multiplexer switches the passive network out of the circuit path and places the first tri-state buffer in a high-impedance state to isolate the passive network.

5. The apparatus according to claim 1, wherein each of the plurality of delay cells further comprise:
a first tri-state buffer;
a plurality of discrete delay elements coupled to the first tri-state buffer;
a second tri-state buffer; and
a multiplexer coupled to the plurality of discrete delay elements and the second tri-state buffer, wherein the delay select command includes a designated bit which controls the first tri-state buffer, the second tri-state buffer, and the multiplexer.

6. The apparatus according to claim 5, wherein a significance of the designated bit in the delay select command corresponds to the number of discrete delay elements in the associated delay cell.

7. The apparatus according to claim 6, wherein the number of discrete delay elements is exponentially proportional to the significance of the designated bit.

8. The apparatus according to claim 5, wherein the discrete delay elements comprise inverters.

9. The apparatus according to claim 5, wherein the first delay cell and each of the plurality of delay cells are connected in series, having the input signal presented at the input of the first delay cell, and an output signal provided at the last delay cell of the plurality of delay cells.

10. The apparatus according to claim 5, wherein if the designated bit is in a low state, the multiplexer switches the plurality of discrete delay elements out of the circuit path and places the first tri-state buffer in a high-impedance state to isolate the plurality of discrete delay elements.

11. The apparatus according to claim 10, further comprising:
a foot switch coupled to the plurality of discrete delay elements, wherein the foot switch turns off a DC bias voltage supplied to the plurality of discrete delay elements when the designated bit is in a low state.

12. The apparatus according to claim 1, wherein the first and second delay stages are realized using CMOS integrated circuit fabrication technology.

13. A method delaying an input signal by a desired time delay, comprising:
receiving a delay select command based upon the desired time delay;
establishing a circuit path which includes at least one delay element, selected from a plurality of delay cells, according to the delay select command, wherein at least one of the plurality of delay cells includes a delay element which comprises a passive network; and
passing an input signal through the established circuit path to achieve a desired time delay of the input signal.

14. The method according to claim 13, further comprising:
provisioning the delay select command as a plurality of designated bits; and
determining circuit sub-paths within each of the plurality of delay cells based upon each delay cell's designated bit, wherein each of the circuit sub-paths are configured to contribute incremental delays based upon the at least one delay element in each delay cell.

15. The method according to 14, further comprising isolating the at least one delay element in each of the plurality of delay cells if the delay cell's designated bit is in a low state.

16. The method according to 15, further comprising:
turning off the at least one delay element's DC bias voltage in each of the plurality of delay cells when the delay cell's designated bit is in a low state.

17. A device for providing a programmable time delay, comprising:
means for receiving a delay select command based upon the desired time delay;
means for establishing a circuit path which includes at least one delay element, selected from a plurality of delay cells, according to the delay select command, wherein at least one of the plurality of delay cells includes a delay element which comprises a passive network; and
means for passing an input signal through the established circuit path to achieve a desired time delay of the input signal.

18. The device according to claim 17, further comprising:
means for provisioning the delay select command as a plurality of designated bits; and
means for determining circuit sub-paths within each of the plurality of delay cells based upon each delay cell's designated bit, wherein each of the circuit sub-paths are configured to contribute incremental delays based upon the at least one delay element in each delay cell.

19. The device according to 18, further comprising:
means for isolating the at least one delay element in each of the plurality of delay cells if the delay cell's designated bit is in a low state.

20. The device according to 19, further comprising:
means for turning off the at least one delay element's DC bias voltage in each of the plurality of delay cells when the delay cell's designated bit is in a low state.
